(19) United States
(12) Patent Application Publication
(10) Pub. No.: US 2017/0170796 A1
(43) Pub. Date: Jun. 15, 2017

(54) ELECTRONIC DEVICE FOR ADJUSTING AN EQUALIZER SETTING ACCORDING TO A USER AGE, SOUND PLAYBACK DEVICE, AND EQUALIZER ADJUSTMENT METHOD

(71) Applicant: Unlimiter MFA Co., Ltd., Eden Island (SC)

(72) Inventors: Neo Bob Chih-Yung YOUNG, Taipei (TW); Kuo-Ping YANG, Taipei (TW)

(21) Appl. No.: 15/089,654

(22) Filed: Apr. 4, 2016

(30) Foreign Application Priority Data
Dec. 11, 2015 (TW) 104220011

(51) Int. Cl. H03G 5/16

(52) U.S. Cl. CPC H03G 5/165

(57) ABSTRACT

An electronic device comprising an equalizer and an equalizer adjustment system is disclosed. The equalizer adjustment system can correspondingly adjust gain value settings of the equalizer for sounds at different frequencies according to a user's age.

### BACKGROUND OF THE INVENTION

1. Field of the Invention

The present invention relates to a technique for adjusting an equalizer; more particularly, the present invention relates to a technique for adjusting the equalizer according to a user's age.

2. Description of the Related Art

An equalizer (EQ) is a tool for adjusting sound output and is capable of adjusting the gain values of sounds at different frequency ranges. Therefore, the equalizer is often used for the adjustment of audio output. Currently; most computers are installed with equalizer software to achieve an entertainment purpose when a user is listening to music.

However, the ability to hear high frequency sounds declines in the elderly; therefore, it will help the elderly people to hear more clearly if the equalizer can make corresponding adjustments to the high frequency portion of the output sound.

Therefore, there is a need to provide an electronic device for adjusting an equalizer setting according to a user's age, a sound playback device and an equalizer adjustment method to mitigate and/or obviate the aforementioned problems.

### SUMMARY OF THE INVENTION

It is an object of the present invention to provide an electronic device capable of an adjusting equalizer setting according to a user's age, a sound playback device, and an equalizer adjustment method.

To achieve the abovementioned objects, the electronic device of the present invention comprises an equalizer and an equalizer adjustment system. The equalizer adjustment system is used for adjusting a setting of the equalizer and comprises an age data acquisition module, a parameter lookup module and a parameter setting module. The age acquisition module is used for acquiring an age data of a user. The parameter lookup module is used for correspondingly obtaining a correction processing parameter according to the age data. The parameter setting module is used for adjusting gain value settings of the equalizer for sounds at different frequencies according to the correction processing parameter.

According to one embodiment of the present invention, the electronic device of the present invention comprises an audio processing chip.

According to one embodiment of the present invention, the abovementioned equalizer is provided in the abovementioned audio processing chip.

According to one embodiment of the present invention, the electronic device of the present invention comprises a sound playback device, and the sound playback device comprises a second audio processing chip and a speaker.

According to one embodiment of the present invention, the abovementioned equalizer is provided in the abovementioned sound playback device.

According to one embodiment of the present invention, the abovementioned equalizer is provided in the second audio processing chip of the abovementioned sound playback device.

According to one embodiment of the present invention, the electronic device of the present invention further comprises a screen, and the age data acquisition module comprises an interface providing unit and a data receiving unit. The interface providing unit is used for providing an input interface so as to allow the user to input the age data via the input interface, and the data receiving unit is used for receiving the inputted age data.

The present invention further discloses a sound playback device which is electrically connected to an electronic device comprising an equalizer adjustment system. The sound playback device of the present invention comprises a second audio processing chip, a signal receiver and an equalizer. The signal receiver is electrically connected to the second audio processing chip. The signal receiver is used for receiving a parameter setting command from the electronic device. The parameter setting command is generated by the equalizer adjustment system according to a correction processing parameter, and the correction processing parameter is generated according to an age data of a user. The parameter setting command is used for adjusting gain value settings of the equalizer for sounds at different frequencies.

The equalizer adjustment method provided by the present invention is applied in an electronic device and is used for adjusting a setting of an equalizer. The equalizer adjustment method of the present invention comprises the following steps: acquiring an age data of a user; according to the age data, correspondingly obtaining a correction processing parameter; and according to the correction processing parameter, adjusting gain value settings of the equalizer for sounds at different frequencies.

Other objects, advantages, and novel features of the invention will become more apparent from the following detailed description when taken in conjunction with the accompanying drawings.

### BRIEF DESCRIPTION OF THE DRAWINGS

These and other objects and advantages of the present invention will become apparent from the following description of the accompanying drawings, which disclose several embodiments of the present invention. It is to be understood that the drawings are to be used for purposes of illustration only, and not as a definition of the invention.

In the drawings, wherein similar reference numerals denote similar elements throughout the several views:

FIG. 1 illustrates a schematic drawing of an implementation environment of an electronic device having an equalizer adjustment system according to a first embodiment of the present invention.

FIG. 2 illustrates a schematic drawing of an implementation environment of the electronic device having the equalizer adjustment system according to a second embodiment of the present invention.

FIG. 3 illustrates a schematic drawing showing the gain value settings of the equalizer in a normal mode.

FIG. 4 illustrates a schematic drawing showing gain value settings of the equalizer in another mode.

FIG. 5 illustrates a schematic drawing of an input interface.

FIG. 6 illustrates a schematic drawing of a database recorded with corresponding relations between age data and correction processing parameters.

FIG. 7 illustrates a schematic drawing showing gain value settings of the equalizer in the normal mode after adjustment.

FIG. 8 illustrates a schematic drawing showing gain value settings of the equalizer in another mode after adjustment.

FIG. 9 illustrates a flowchart of an equalizer adjustment method according to the present invention.

### DETAILED DESCRIPTION OF THE PREFERRED EMBODIMENT

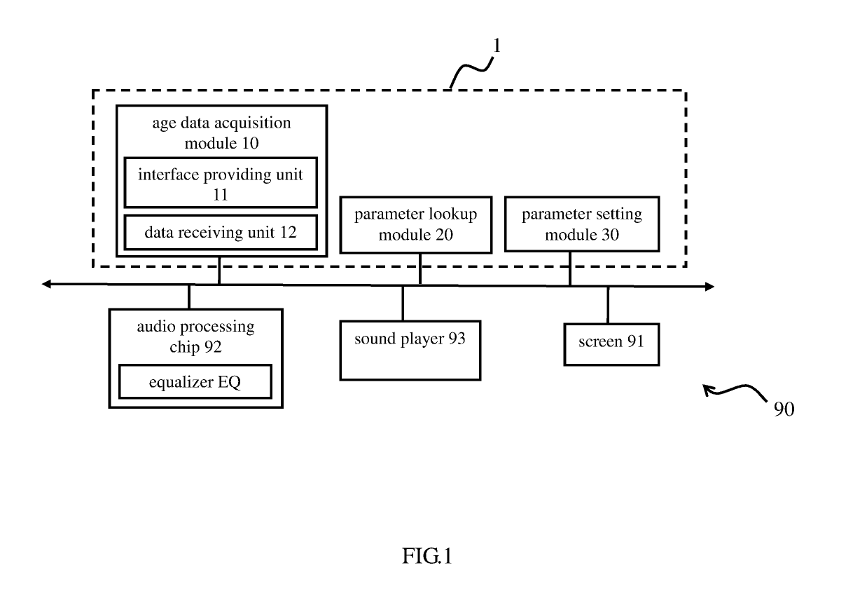

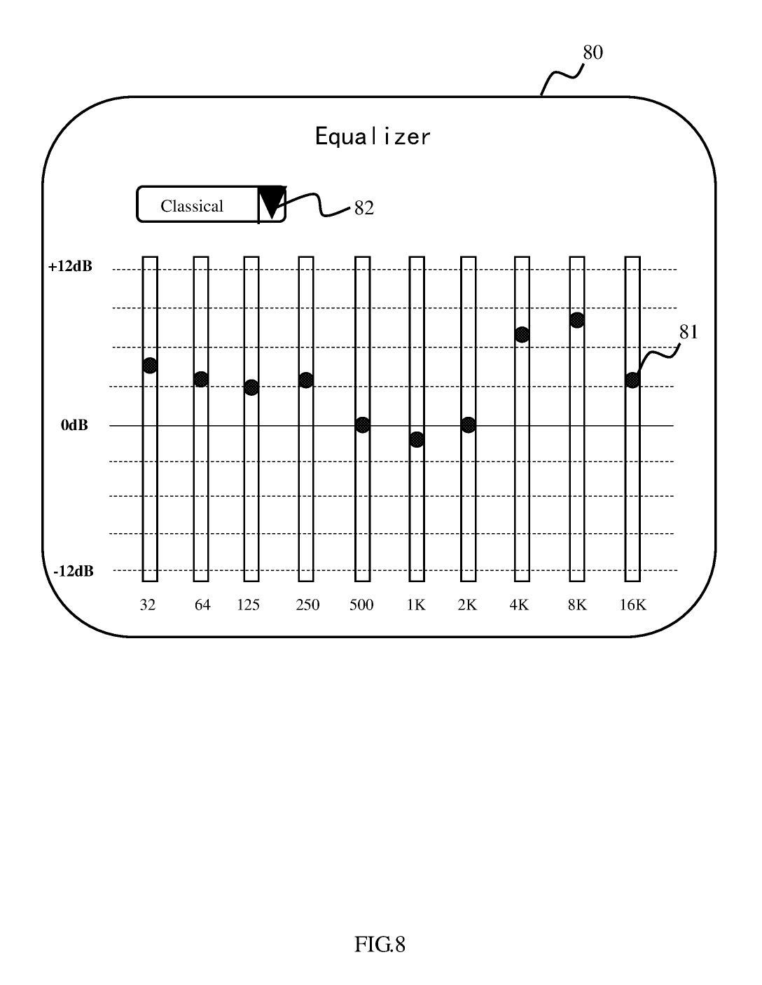

Please refer to FIG. 1 to FIG. 8, which are schematic drawings of an implementation environment of an electronic device 90 according to the present invention.

As shown in FIG. 1, in a first embodiment of the present invention, the electronic device 90 of the present invention comprises a screen 91, an audio processing chip 92, a sound player 93, an equalizer EQ and an equalizer adjustment system 1. The equalizer adjustment system 1 is electrically connected to the screen 91, the audio processing chip 92 and the sound player 93. In a specific embodiment of the present invention, the electronic device 90 is, but is not limited to, a smart phone. The electronic device 90 can also be a tablet computer, a laptop computer or other equivalent electronic product having operation processing capabilities.

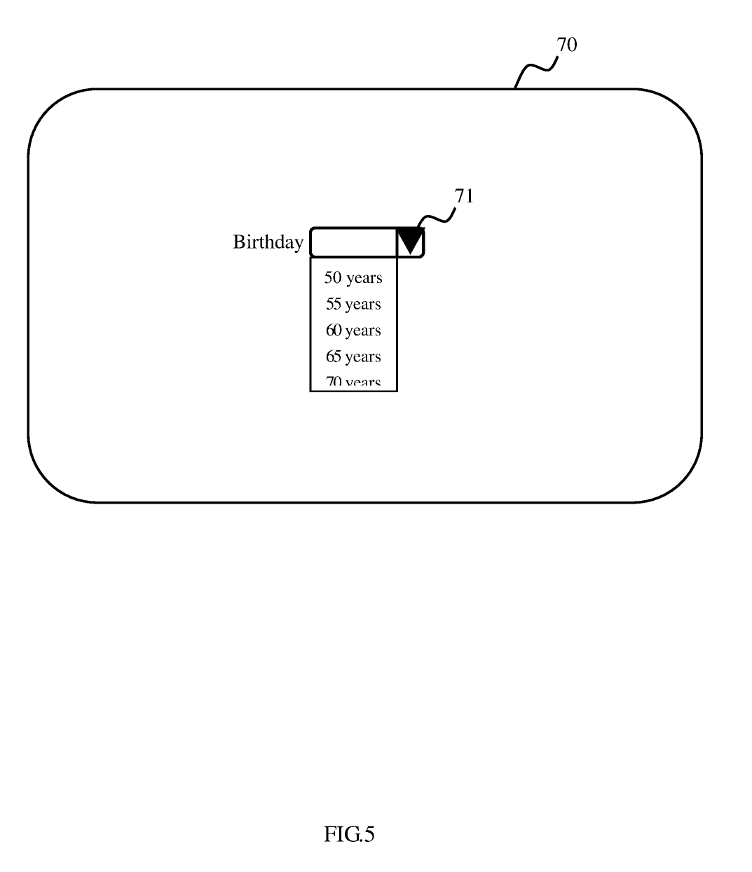

The screen 91 is used for displaying an image. In one embodiment of the present invention, the screen 91 can display an input interface 70 as shown in FIG. 5 so as to allow a user to input an age value via the input interface 70.

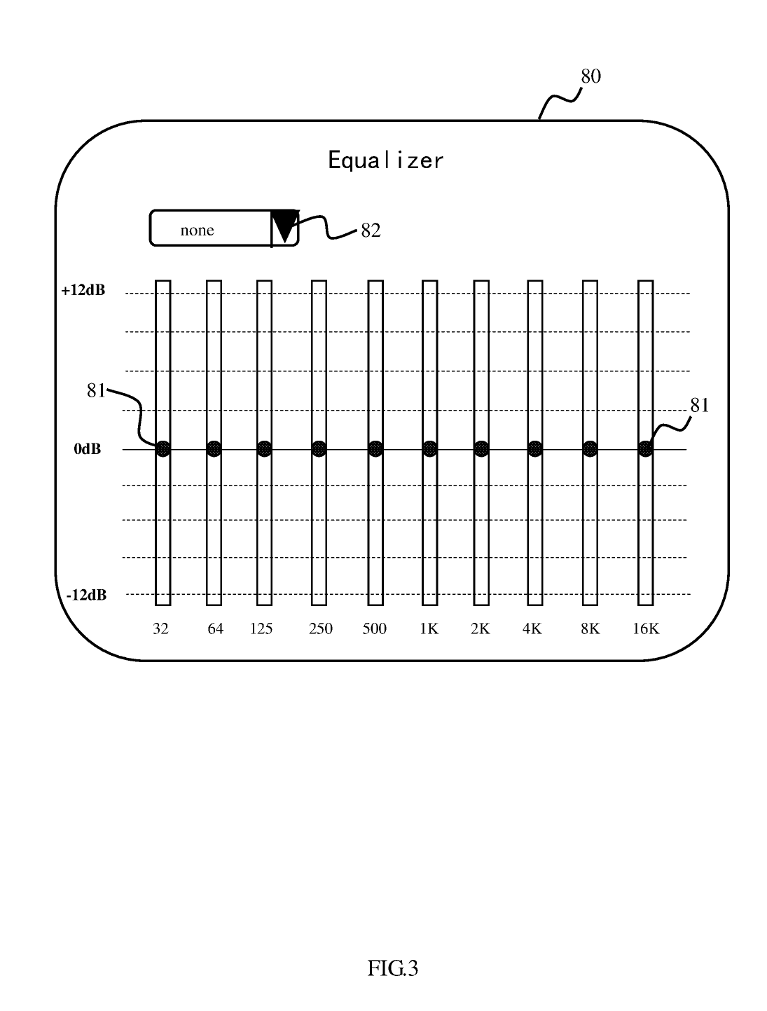

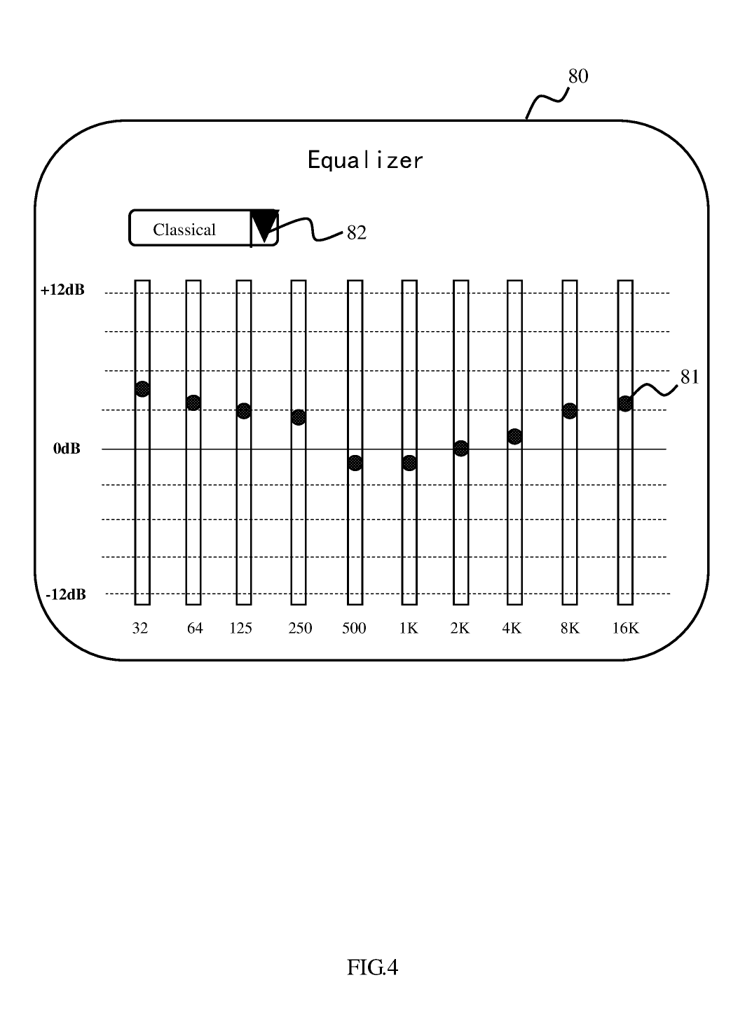

In the first embodiment of the present invention, the audio processing chip 92 is used for performing an audio encoding/decoding process, wherein the audio processing chip 92 is installed with equalizer EQ software (firmware). In other words, in this embodiment, the equalizer EQ is disposed in the audio processing chip 92. By means of adjusting a gain value setting of the equalizer EQ, the present invention allows adjustment of the gain value of the audio processing chip 92 for sounds at different frequencies. Generally, the user can adjust the gain value setting of the equalizer EQ via a graphical interface 80, as shown in FIG. 3 or FIG. 4. FIG. 3 illustrates a schematic drawing showing gain value settings of the equalizer EQ in a normal mode. In the normal mode, the gain values of sounds at each frequency are equal. If the user wants to increase the frequency of the output sound, the user can manually increase the gain value of a high frequency portion (2K˜16 KHz) via an adjustment button 81. In addition, a conventional equalizer EQ is pre-configured with multiple modes for the user to select, so the user can select a desired mode via a mode selection menu 82. FIG. 4 illustrates a schematic drawing showing gain value settings of the equalizer EQ in another mode. There are different gain value settings in different modes. Because the equalizer EQ is a common sound output adjustment tool, the structure and theory are well known by those skilled in the art, and there is no need for further description.

The sound player 93, such as a built-in speaker or an external earphone, is used for producing sounds according to sound signals encoded and generated by the audio processing chip 92.

In the first embodiment of the present invention, the equalizer adjustment system 1 comprises an age data acquisition module 10, a parameter lookup module 20 and a parameter setting module 30. Please note that each of the abovementioned modules can be a hardware device, a software program, a firmware or a combination thereof and that the modules also can be a circuit loop or any other applicable arrangement. Furthermore, each module can be arranged independently or integrally In a preferred embodiment, each module is a software program and is stored in a memory such that the object of the present invention can be achieved by executing each module via a processor (not shown in figures) of the electronic device 90. Moreover, this embodiment is only one example of a preferred embodiment of the present invention; not all possible variations and combinations are described in detail. However, those who are skilled in the art may understand that not all of the above modules or elements are necessary. Also, in order to implement the present invention, other more detailed known modules or elements may be used. Each module or element may be omitted or modified according to different needs, and other modules or elements may be provided between any two modules without limiting the scope of the present invention.

In one embodiment of the present invention, the age data acquisition module 10 comprises an interface providing unit 11 and a data receiving unit 12. The interface providing unit 11 is used for providing an input interface 70 as shown in FIG. 5 displayed on the screen 91. The input interface 70 comprises a selection menu scroll bar 71 which allows the user to select and input the age data. After the user inputs the age data via the input interface 70, the inputted age data will be received by the data receiving unit 12. Please note that the method of acquiring the age data is not limited to the above embodiment and that the age data can be acquired without the need for inputting an exact age of the user; that is, the age data can also be acquired from indirect information such as the user's date of birth.

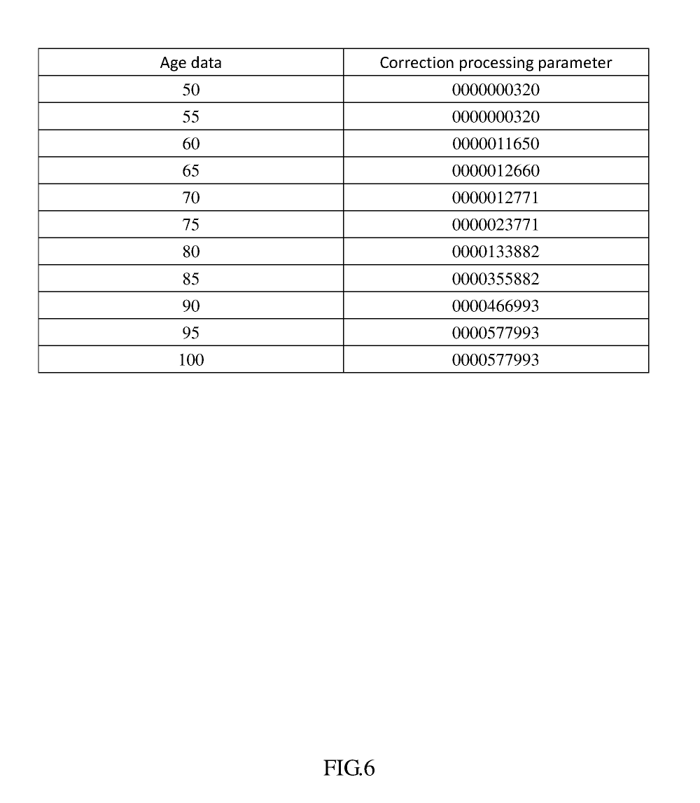

The parameter lookup module 20 is used for correspondingly obtaining a correction processing parameter according to the received age data. FIG. 6 illustrates a schematic drawing of a database containing corresponding relations between age data and correction processing parameters. The database can be pre-stored in the electronic device 90 in advance. After the user inputs the age data, the parameter lookup module 20 can look up a correction processing parameter corresponding to the inputted age data by means of table look-up. For example, if the age data inputted by the user is 60 years old, the parameter lookup module 20 will correspondingly generate a correction processing parameter of “0000011650” according to the inputted age data.

The parameter setting module 30 is used for generating a parameter setting command according to the correction processing parameter. The parameter setting command is used for adjusting a gain value setting of the equalizer EQ for sounds at different frequencies. For example, different digits, from left to right, in the correction processing parameter respectively represent values for adjusting the gain value at different frequencies. Therefore, in the case that the correspondingly obtained correction processing parameter is “0000011650”, the parameter setting command generated according to the correction processing parameter is used for increasing the gain value at frequencies of 1 KHz and 2 KHz by 1 dB, increasing the gain value at the frequency of 4 KHz by 6 dB, and increasing the gain value at the frequency of 8 KHz by 5 dB.

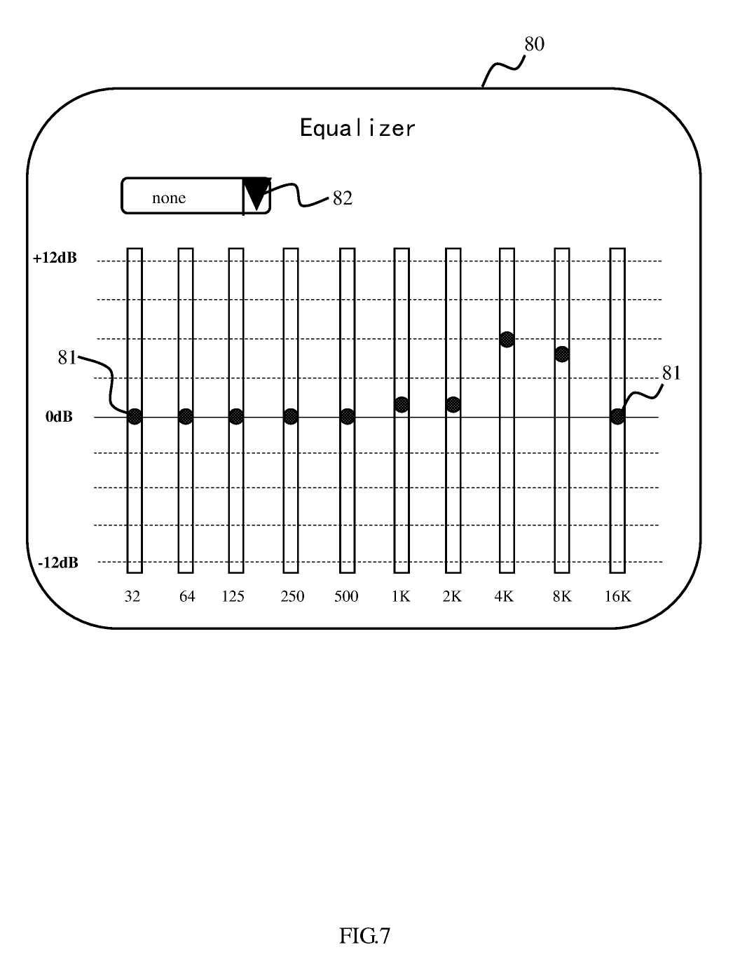

After the parameter setting module 30 completes the adjustment, the gain values of the equalizer EQ in each mode are synchronously set to new gain values. Using the above example for explanation, in each mode, the gain value at 4 KHz will be 6 dB higher than its original gain value (as shown in FIG. 6 and FIG. 7), and the gain values at other frequencies will be adjusted as well.

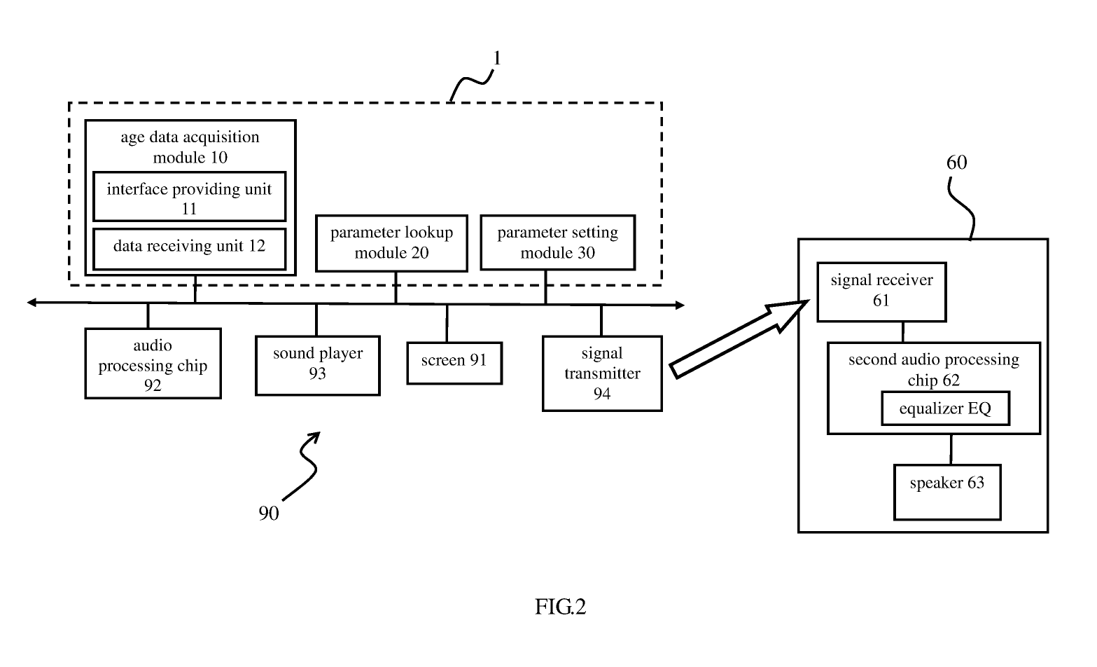

Please refer to FIG. 2, which illustrates a schematic drawing of an implementation environment of the electronic device 90 according to a second embodiment of the present invention. The second embodiment of the present invention differs from the first embodiment in that the electronic device 90 further comprises a sound playback device 60 and a signal transmitter 94. The sound playback device 60 comprises a signal receiver 61, a second audio processing chip 62 and a speaker 63. The signal transmitter 94 and the signal receiver 61 have a signal connection via wireless communications. In a preferred embodiment of the present invention, the sound playback device 60 is, but is not limited to, a wireless earphone.

The signal receiver 61 is used for connecting to the signal transmitter 94 for receiving the parameter setting command generated from the equalizer adjustment system 1 or for receiving audio signals (such as music). In a specific embodiment of the present invention, the signal receiver 61 and the signal transmitter 94 are both Bluetooth wireless communication modules. In other words, in this embodiment, the sound playback device 60 is connected to the electronic device 90 via wireless communications; however, please note that the scope is not limited to the above embodiment.

The second audio processing chip 62 is electrically connected to the signal receiver 61 and the speaker 63, and comprises an equalizer EQ. The parameter setting command from the electronic device 90 can be used for adjusting the gain value setting of the equalizer EQ for sounds at different frequencies such that the second audio processing chip 62 can process later-inputted sound signals according to the adjusted gain value setting of the equalizer EQ, thereby generating an output sound signal, such that the speaker 63 can produce sounds according to the output sound signal. In a specific embodiment of the present invention, the second audio processing chip 62 is a microcontroller, and the equalizer EQ is disposed in the microcontroller by way of software (firmware) without limiting the scope of the present invention.

The remaining devices or elements of the equalizer adjustment system 1 and the electronic device 90 not mentioned in the second embodiment have the same functions as described in the abovementioned first embodiment; therefore, there is no need for further elaboration.

According to the above description, the equalizer adjustment system 1 of the present invention can correspondingly adjust the setting of the equalizer EQ according to the age data inputted by the user such that the sounds produced by the electronic device 90 or the sound playback device 60 after the adjustment can be suitable for the hearing condition of the user corresponding to his/her age.

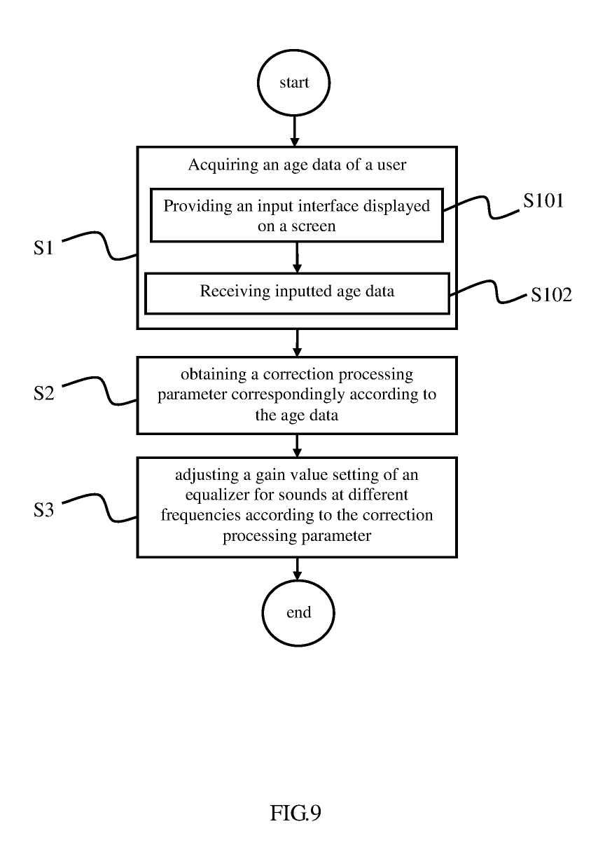

Finally, please refer to FIG. 1 to FIG. 9, wherein FIG. 9 illustrates a flowchart of an equalizer adjustment method according to the present invention. FIG. 1 to FIG. 8 are referenced for explaining the steps shown in FIG. 9 sequentially. Please note that the electronic device 90 as shown in FIG. 1 or FIG. 2 is only used as an example for explaining the equalizer adjustment method disclosed in the present invention without limiting the scope of the present invention.

First, the method performs step S1: acquiring an age data of a user.

The equalizer adjustment method disclosed in the present invention is used for correspondingly adjusting gain value settings of the equalizer EQ according to the user's age. Therefore, in order to know the user's age, the first step of the equalizer adjustment method is to acquire the age data of the user. In an embodiment of the present invention, step S1 of acquiring the age data of the user includes sub-steps S101 and S102

Step S101: providing an input interface displayed on a screen.

In one embodiment of the present invention, in order to acquire the age data of the user, the equalizer adjustment method of the present invention first utilizes the interface providing unit 11 of the age data acquisition module 10 to provide the input interface 70 as shown in FIG. 5 displayed on the screen 91 so as to allow the user to input the age data via the input interface 70.

Step S102: receiving inputted age data.

After the age data has been inputted, the data receiving unit 12 of the age data acquisition module 10 receives the age data inputted by the user via the input interface 70.

Step S2: obtaining a correction processing parameter correspondingly according to the age data.

After receiving the age data inputted by the user, the parameter lookup module 20 correspondingly obtains the correction processing parameter according to the inputted age data by means of table look-up (wherein the database having the corresponding relations is shown in FIG. 6 as an example, and the database can be pre-stored in the electronic device 90 in advance). Using the corresponding relations as shown in FIG. 6 as an example, if the age data inputted by the user is 60 years old, the parameter lookup module 20 will correspondingly generate a correction processing parameter of “0000011650” according to the inputted age data.

Step S3: adjusting gain value settings of an equalizer for sounds at different frequencies according to the correction processing parameter.

After the correction processing parameter is generated, finally, the parameter setting module 30 generates a parameter setting command according to the correction processing parameter. The parameter setting command adjusts gain value settings of the equalizer EQ (either provided in the electronic device 90 or provided in the sound playback device 60) for sounds at different frequencies such that the sounds produced by the electronic device 90 or the sound playback device 60 after the adjustment are suitable for the general hearing condition of the user according to the inputted age, thereby optimizing the output sound effect for the specific user.

Although the present invention has been explained in relation to its preferred embodiments, it is to be understood that many other possible modifications and variations can be made without departing from the spirit and scope of the invention as hereinafter claimed.

What is claimed is:

1. An electronic device, comprising:
an equalizer; and
an equalizer adjustment system, used for adjusting a setting of the equalizer, the equalizer adjustment system comprising:
an age data acquisition module, used for acquiring an age data of a user;
a parameter lookup module, used for correspondingly obtaining a correction processing parameter according to the age data; and
a parameter setting module, used for adjusting gain value settings of the equalizer for sounds at different frequencies according to the correction processing parameter.

2. The electronic device as claimed in claim 1, further comprising an audio processing chip.

3. The electronic device as claimed in claim 2, wherein the equalizer is disposed in the audio processing chip.

4. The electronic device as claimed in claim 1, further comprising a sound player, wherein the sound playback device comprises a second audio processing chip and a speaker.

5. The electronic device as claimed in claim 4, wherein the equalizer is disposed in the sound playback device.

6. The electronic device as claimed in claim 5, wherein the equalizer is disposed in the second audio processing chip.

7. The electronic device as claimed in claim 1, further comprising a screen, and the age data acquisition module comprising an interface providing unit and a data receiving unit; the interface providing unit is used for providing an input interface displayed on the screen such that the user can input the age data via the input interface, and the data receiving unit is used for receiving the inputted age data.

8. A sound playback device, electrically connected to an electronic device, the electronic device comprising an equalizer adjustment system, the audio playback device comprising:
a second audio processing chip;
a signal receiver, electrically connected to the second audio processing chip, used for receiving a parameter setting command from the electronic device, wherein the parameter setting command is generated by the equalizer adjustment system according to a correction processing parameter, and the correction processing parameter is obtained by the equalizer adjustment system according to an age data of a user; and
an equalizer, wherein the parameter setting command is used for adjusting gain value settings of the equalizer for sounds at different frequencies.

9. The sound playback device as claimed in claim wherein e equalizer is disposed in the second audio processing chip.

10. An equalizer adjustment method, applied in an electronic device, used for adjusting a setting of an equalizer, the equalizer adjustment method comprising the following steps:
acquiring an age data of a user;
obtaining a correction processing parameter correspondingly according to the age data; and
adjusting gain value settings of the equalizer for sounds at different frequencies according to the correction processing parameter.

11. The equalizer adjustment method as claimed in claim 10, wherein the electronic device comprises a screen, and the step of obtaining the age data further comprises the following steps:
providing an input interface displayed on the screen; and
receiving the age data inputted via the input interface.
